(19) United States
(12) Patent Application Publication
(10) Pub. No.: US 2025/0364229 A1
(43) Pub. Date: Nov. 27, 2025

(54) CERAMIC JOINED BODY, ELECTROSTATIC CHUCK DEVICE, AND METHOD FOR MANUFACTURING CERAMIC JOINED BODY

(71) Applicant: SUMITOMO OSAKA CEMENT CO., LTD., Tokyo (JP)

(72) Inventors: Jun ARIKAWA, Tokyo (JP); Nobuhiro HIDAKA, Tokyo (JP); Yukio MIURA, Tokyo (JP); Shinichi MAETA, Tokyo (JP)

(73) Assignee: SUMITOMO OSAKA CEMENT CO., LTD., Tokyo (JP)

(21) Appl. No.: 18/688,270

(22) PCT Filed: Jan. 18, 2023
(86) PCT No.: PCT/JP2023/001264

§ 371 Date: Feb. 7, 2025

(30) Foreign Application Priority Data
Jan. 31, 2022 (JP) 2022-012942

(51) Int. Cl. H01J 37/32; C04B 37/00; H01J 9/30

(52) U.S. Cl. CPC H01J 37/32724; C04B 37/005; H01J 9/30; H01J 37/32467; H01J 37/32559; C04B 2237/704; H01J 2237/0213; H01J 2237/038; H01J 2237/2007

(57) ABSTRACT

A ceramic joined body includes: a pair of ceramic plates; an electrode layer that is interposed between the pair of ceramic plates; and a joining layer that is disposed in a periphery of the electrode layer between the pair of ceramic plates, in which at least one of the pair of ceramic plates and the joining layer is formed of a composite of an insulating material and a conductive material, a gap is provided between an outer edge of the electrode layer and an inner edge of the joining layer, and a content ratio of the conductive material in the at least one of the pair of ceramic plates and the joining layer is 3% by mass or more and 12% by mass or less.

### TECHNICAL FIELD

The present invention relates to a ceramic joined body, an electrostatic chuck device, and a method for manufacturing a ceramic joined body.

This application claims priority based on Japanese Patent Application No. 2022-012942 filed on Jan. 31, 2022, the content of which is incorporated herein by reference.

### Background Art

In the related art, in a semiconductor manufacturing step of manufacturing a semiconductor device such as IC, LSI, or VLSI, a plate-shaped sample such as a silicon wafer is fixed to an electrostatic chuck member having an electrostatic chuck function by electrostatic adsorption, and a predetermined process is performed thereon.

For example, when the plate-shaped sample is etched in a plasma atmosphere, a surface of the plate-shaped sample is heated to a high temperature by heat of the plasma, and there may be a problem in that, for example, a resist film of the surface is burst.

Here, in order to maintain the temperature of the plate-shaped sample at a desired given temperature, an electrostatic chuck device having a cooling function is used. The electrostatic chuck device includes the above-described electrostatic chuck member and a base member for temperature adjustment where a flow path that circulates a coolant for temperature control to the inside of a metal member is formed. The electrostatic chuck member and the base member for temperature adjustment are joined and integrated through a silicone adhesive on a lower surface of the electrostatic chuck member.

In this electrostatic chuck device, the coolant for temperature adjustment is circulated for heat exchange to the flow path of the base member for temperature adjustment such that electrostatic adsorption can be performed while maintaining the temperature of the plate-shaped sample fixed to an upper surface of the electrostatic chuck member to a desired given temperature. Therefore, by using the above-described electrostatic chuck device, various plasma treatments can be performed on the plate-shaped sample while maintaining the temperature of the plate-shaped sample to be electrostatically adsorbed.

As the electrostatic chuck member, a configuration including a ceramic joined body that includes a pair of ceramic plates and an electrode layer interposed between the pair of ceramic plates is known. As a method for manufacturing the ceramic joined body, for example, there is known a method including: forming a groove in one ceramic sintered compact; forming a conductive layer in the groove; grinding and mirror-polishing the conductive layer together with the ceramic sintered compact; and joining the one ceramic sintered compact to another ceramic sintered compact by hot press (for example refer to Patent Literature No. 1).

### CITATION LIST

### Patent Literature

[Patent Literature No. 1] Japanese Patent No. 5841329

### SUMMARY OF INVENTION

### Technical Problem

When the method of Patent Literature No. 1 is adopted, there is a problem in that the number of manufacturing steps increases and the ceramic joined body becomes expensive.

On the other hand, as a method for inexpensively and stably manufacturing a ceramic joined body, a method in which a paste for formation of electrode layer is applied to and filled in a recess portion of a ceramic plate and is solidified after laminating the ceramic plate is known. In this method, unlike the method of Patent Literature No. 1, the lamination of the ceramic plate and formation of a conductive layer are performed at the same time. Therefore, the number of manufacturing steps can be reduced as compared to the method of Patent Literature No. 1. On the other hand, when this method is adopted, there is a concern that a fine gap may remain in an interface (joint interface) between the ceramic plate and an electrode side surface. This fine gap may cause a decrease in the withstand voltage of the ceramic joined body.

In order to suppress the formation of the above-described gap, the recess portion of the ceramic plate needs to be filled with the paste for formation of electrode layer. However, when the amount of the paste for formation of electrode layer applied increases to remove the gap, the paste for formation of electrode layer may protrude from the recess portion, and it is difficult to stably fill the paste for formation of electrode layer. It is pointed out that the protrusion portion of the electrode layer causes breakdown of the ceramic joined body. That is, when it is attempted to remove the fine gap to increase the withstand voltage of the ceramic joined body, there is a concern that the withstand voltage may decrease on the contrary.

The present invention has been made in consideration of the above-described circumstances, and an object thereof is to provide a ceramic joined body where the occurrence of breakdown in a ceramic plate caused by discharge is suppressed when a high voltage is applied, an electrostatic chuck device, and a method for manufacturing a ceramic joined body.

### Solution to Problem

In order to achieve the above-described object, the present invention includes the following aspects.
[1] A ceramic joined body including:
a pair of ceramic plates;
an electrode layer that is interposed between the pair of ceramic plates; and
a joining layer that is disposed in a periphery of the electrode layer between the pair of ceramic plates,
in which the joining layer and at least one of the pair of ceramic plates are formed of a composite of an insulating material and a conductive material,
a gap is provided between an outer edge of the electrode layer and an inner edge of the joining layer, and
a content ratio of the conductive material in the joining layer and the at least one of the pair of ceramic plates is 3% by mass or more and 12% by mass or less.
[2] The ceramic joined body according to [1],
in which the inner edge of the joining layer has an inclination with respect to a thickness direction of the pair of ceramic plates, the electrode layer, and the joining layer.
[3] The ceramic joined body according to [1] or [2],
in which the insulating material is at least one selected from the group consisting of Al₂O₃, AlN, Si₃N₄, Y₂O₃, YAG, SmAlO₃, MgO, and SiO₂.
[4] The ceramic joined body according to any one of [1] to [3],
in which the conductive material is at least one selected from the group consisting of SiC, TiO₂, TiN, TiC, W, WC, Mo, Mo₂C, and C.
[5] The ceramic joined body according to any one of [1] to [4],
in which the joining layer is integrally formed with one of the pair of ceramic plates.
[6] The ceramic joined body according to any one of [1] to [5],
in which a width dimension of the gap between the outer edge of the electrode layer and the inner edge of the joining layer is 50 μm or higher.
[7] The ceramic joined body according to any one of [1] to [6],
in which at least one of the pair of ceramic plates includes a protrusion portion that protrudes to a side of an other one of the ceramic plates, and the protrusion portion is located in a portion where a surface facing the other ceramic plate overlaps the electrode layer when seen from a thickness direction thereof.
[8] The ceramic joined body according to any one of [1] to [7],
in which a minimum value of a width dimension of the joining layer is 0.3 mm or higher and 3 mm or lower.
[9] An electrostatic chuck device,
in which an electrostatic chuck member formed of a ceramic and a base member for temperature adjustment formed of a metal are joined through an adhesive layer, and
the electrostatic chuck member is formed of the ceramic joined body according to any one of [1] to [8].
[10] A method for manufacturing a ceramic plate joined body in which an electrode layer is provided between a pair of ceramic plates, the method including:
a first step of forming a recess portion in at least one of the pair of ceramic plates;
a second step of forming an electrode layer coating film on a bottom surface of the recess portion;
a third step of laminating the pair of ceramic plates to cover an opening of the recess portion; and
a fourth step of pressurizing the pair of ceramic plates laminated in the third step in a thickness direction while heating the pair of ceramic plates,
in which in the second step, a gap is provided between an outer edge of the electrode layer coating film and a side wall surface of the recess portion, and
in the second step, a thickness dimension of the electrode layer coating film is 0.85 times or higher and 1.5 times or lower with respect to a depth dimension of the recess portion.

### Advantageous Effects of Invention

According to the present invention, by providing the gap between the outer edge of the electrode layer and the inner edge of the joining layer, the protrusion of the electrode layer is suppressed. As a result, breakdown caused by concentration of charge in the protrusion portion of the electrode layer is suppressed. Further, in order to suppress the bias of charge distributed in the gap, the ceramic plate and the joining layer include the conductive material. As a result, it is possible to provide a ceramic joined body where the occurrence of breakdown in a ceramic plate caused by discharge is suppressed even when a high voltage is applied, an electrostatic chuck device, and a method for manufacturing a ceramic joined body.

### BRIEF DESCRIPTION OF DRAWINGS

FIG. 1 is a cross-sectional view showing a ceramic joined body according to one embodiment of the present invention.

FIG. 2 is a cross-sectional view showing an electrostatic chuck device according to one embodiment of the present invention.

FIG. 3 is a partial cross-sectional view showing a ceramic joined body according to a modification example of the present embodiment.

FIG. 4 is a schematic cross-sectional view showing a ceramic joined body according to a comparative example.

FIG. 5 is a schematic cross-sectional view showing a ceramic joined body according to a reference example.

FIG. 6 is a schematic diagram showing a first step of a method for manufacturing a ceramic joined body according to one embodiment.

FIG. 7 is a schematic diagram showing a second step of the method for manufacturing a ceramic joined body according to the embodiment.

FIG. 8 is a schematic diagram showing a third step of the method for manufacturing a ceramic joined body according to the embodiment.

### DESCRIPTION OF EMBODIMENTS

Embodiments of a ceramic joined body and an electrostatic chuck device according to the present invention will be described.

The embodiments will be described in detail for easy understanding of the concept of the present invention, but the present invention is not limited thereto unless specified otherwise.

### [Ceramic Joined Body]

### First Embodiment

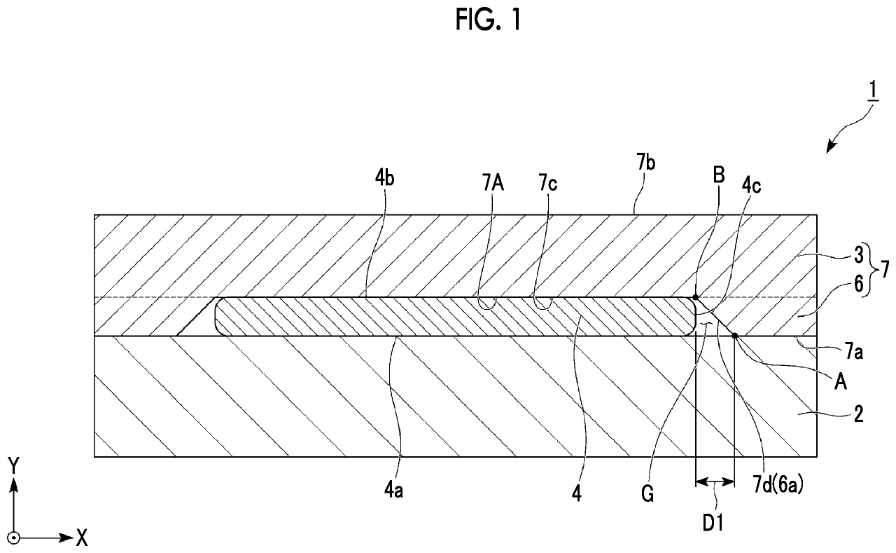

Hereinafter, a ceramic joined body according to one embodiment of the present invention will be described with reference to FIG. 1. In FIG. 1, note that a horizontal direction of the paper plane (width direction of the ceramic joined body) is an X direction, a vertical direction of the paper plane (thickness direction of the ceramic joined body) is a Y direction, and a depth direction of the paper plane is a Z direction.

In all of the following drawings, dimensions, ratios, and the like of the components may be appropriately different from the actual ones in order to easily understand the drawings.

FIG. 1 is a cross-sectional view showing the ceramic joined body according to the present embodiment. As shown in FIG. 1, the ceramic joined body 1 according to the present embodiment includes: a pair of ceramic plates 2 and 3; and an electrode layer 4 and a joining layer 6 that are interposed between the pair of ceramic plates 2 and 3. Hereinafter, the ceramic plate 2 will be referred to as the first ceramic plate 2, and the ceramic plate 3 will be referred to as the second ceramic plate 3.

In the present embodiment, a thickness direction of the pair of ceramic plates 2 and 3, the electrode layer 4, and the joining layer 6 match with each other. In the following description, the thickness direction (that is, a Y-axis direction in FIG. 1) of the pair of ceramic plates 2 and 3, the electrode layer 4, and the joining layer 6 will also be simply referred to as “thickness direction”. In addition, a direction (that is, a plane direction of an X-Z plane in FIG. 1) orthogonal to the thickness direction will also be simply referred to as “side surface direction”.

When a minimum circle among circles circumscribing the ceramic joined body 1 in a plan view is assumed, the cross-sectional view shown in FIG. 1 is a cross-section of the ceramic joined body taken along a virtual plane including the center of the circle. When the ceramic joined body 1 is substantially circular in a plan view, the center of the circle and the center of the shape of the ceramic joined body in a plan view substantially match each other.

As described below, “gap” between members is formed in the ceramic joined body according to the present embodiment. In the following description, the size of the gap is evaluated based on “the width dimension of the gap”. “The width dimension of the gap” refers to the width dimension of the gap in the direction orthogonal to the thickness direction of the ceramic joined body 1 in a cross-section passing through the center of the circle. In FIG. 1, the width dimension of the gap is represented by reference numeral D1.

In the present specification, “plan view” refers to a view seen from the Y direction that is the thickness direction of the ceramic joined body. In addition, in the present specification, “outer edge” refers to a region in the vicinity of an outer periphery of an object in a plan view.

In the present embodiment, the joining layer 6 and the second ceramic plate 3 are formed as a single member. That is, the joining layer 6 is integrally formed with one of the pair of ceramic plates 2 and 3 (in the present embodiment, the second ceramic plate 3). In the following description, a portion including the second ceramic plate 3 and the joining layer 6 will be referred to as a laminated portion 7. That is, the laminated portion 7 includes the second ceramic plate 3 and the joining layer 6. The second ceramic plate 3 and the joining layer 6 may be separate members. In addition, the first ceramic plate 2 and the joining layer 6 may be integrally formed to form the laminated portion.

The joining layer 6 is annularly disposed in the periphery of the electrode layer 4 between the first ceramic plate 2 and the second ceramic plate 3. That is, the ceramic joined body 1 is a joined body where the first ceramic plate 2 and the second ceramic plate 3 are joined and integrated through the electrode layer 4 and the joining layer 6.

In the ceramic joined body 1, the first ceramic plate 2, the electrode layer 4, and the laminated portion 7 are laminated in this order. The laminated portion 7 includes a joint surface 7a facing the first ceramic plate 2 side. The laminated portion 7 is joined to the first ceramic plate 2 on the joint surface 7a. In the laminated portion 7, a recess portion 7A that is recessed in a +Y direction (in the thickness direction of the laminated portion 7) from the joint surface 7a toward a surface 7b side opposite to the joint surface 7a is formed. The recess portion 7A is circular in a plan view, and the opening diameter thereof in the +Y direction gradually decreases. That is, a space surrounded by the recess portion 7A has a truncated cone shape.

The recess portion 7A includes: a bottom surface 7c parallel to the surface 7b of the laminated portion 7; and a side wall surface 7d extending from the bottom surface 7c toward the joint surface 7a side. The bottom surface 7c is one surface of the second ceramic plate 3 and is a surface facing the first ceramic plate 2. The bottom surface 7c is in contact with the electrode layer 4. The side wall surface 7d is one surface of the joining layer 6 and forms an inner edge 6a of the joining layer 6. The side wall surface 7d surrounds the electrode layer 4. The side wall surface 7d is obliquely inclined with respect to the thickness direction. The side wall surface 7d is inclined in a direction in which the opening diameter increases toward the opening side of the recess portion 7A (that is, the first ceramic plate 2 side).

The electrode layer 4 is formed of an electrode layer coating film that is formed by applying (filling) a paste for formation of electrode layer to the recess portion 7A. Accordingly, the second ceramic plate 3 and the electrode layer 4 are joined on the bottom surface 7c of the recess portion 7A. The electrode layer 4 is embedded in the recess portion 7A of the laminated portion 7. That is, the thickness of the electrode layer 4 is the same as the depth of the recess portion 7A.

The recess portion 7A according to the present embodiment is not completely filled with the electrode layer 4. A gap G is provided between an outer edge 4c of the electrode layer 4 and the side wall surface 7d of the recess portion 7A in the present embodiment. That is, the gap G is provided between the outer edge 4c of the electrode layer 4 and the inner edge 6a of the joining layer 6. The gap G annularly extends in a circumferential direction along the side wall surface 7d of the recess portion 7A. Therefore, as compared to a case where a gap is locally formed, charge accumulated in the gap G can be distributed in the circumferential direction with a good balance. As a result, local concentration of charge can be suppressed, and breakdown of the ceramic joined body caused by the concentration of charge can be suppressed.

As long as the gap G is provided in even a part of the outer edge 4c of the electrode layer 4 and the inner edge 6a of the joining layer 6, the outer edge 4c and the inner edge 6a may be in contact with each other in another part. Here, as shown in FIG. 1, it is assumed that an intersection point between the bottom surface 7c of the recess portion 7A and the side wall surface 7d is a position B, and an intersection point between the side wall surface 7d and the joint surface 7a is a position A. Since the side wall surface 7d is inclined, there is a case where the electrode layer 4 reaches the position B without reaching the position A. That is, the gap G only needs to be provided between the position A and the outer edge 4c of the electrode layer 4. As shown in FIG. 1, a width dimension D1 of the gap G is defined as the distance in the side surface direction from the position A to the outer edge 4c of the electrode layer 4.

In addition, the electrode layer 4 is a thin electrode that is wider in a direction (side surface direction) orthogonal to the thickness direction than in the thickness direction. For example, the electrode layer 4 has a disk shape having a thickness of 20 μm and a diameter of 29 cm. As described below, the electrode layer 4 can be formed by applying and sintering a paste for formation of electrode layer. The paste for formation of electrode layer is likely to isotropically shrink by sintering during volume shrinkage. Therefore, the shrinkage amount in the side surface direction is more than that in the thickness direction. Therefore, the gap G is likely to be structurally formed in an interface between the outer edge 4c of the electrode layer 4 and the inner edge 6a of the joining layer 6. On the other hand, when the paste for formation of electrode layer is widely applied in advance to prevent the gap G from being provided, there is a concern that the electrode layer 4 may protrude from the recess portion 7A, for example, when the shrinkage is smaller than expected. In this case, when a high voltage is applied to the ceramic joined body 1, discharge is likely to occur in an interface between the electrode layer 4 protruding from the recess portion 7A and the joining layer 6.

In the ceramic joined body 1 according to the present embodiment, the formation of the gap G between the outer edge 4c of the electrode layer 4 and the inner edge 6a of the joining layer 6 is allowed. In addition, in the ceramic joined body 1, charge accumulated in the gap G is substantially uniformly distributed in the circumferential direction of the ceramic joined body 1 by suppressing bias. More specifically, as described below by allowing either or both of the pair of ceramic plates 2 and 3 and a ceramic material of the joining layer 6 to include a conductive material, the charge in the gap G can be moved to be uniformly distributed along the circumferential direction. As a result, concentration and accumulation of charge in a part of the gap G can be suppressed, and breakdown caused by the local concentration of charge can be suppressed, and the withstand voltage of the ceramic joined body 1 can be increased.

The width dimension D1 of the gap G is preferably 500 μm or lower. The heat capacity of the ceramic joined body 1 varies between a location where the gap G is present and a location where the gap G is not present. When the width dimension D1 of the gap G exceeds 500 μm, in the periphery of the electrode layer 4, the heat capacity of the ceramic joined body 1 largely varies in the plane direction of the ceramic joined body 1, and it is difficult to maintain the in-plane temperature uniformity of the ceramic joined body 1. That is, by adjusting the width dimension D1 of the gap G to be 500 μm or lower, the in-plane temperature uniformity of the ceramic joined body 1 during application of high frequency power is maintained. From the viewpoint of the in-plane temperature uniformity of the ceramic joined body 1, the width dimension D1 of the gap G is more preferably 400 μm or lower and still more preferably 250 μm or lower.

Further, from the viewpoint of the performance of the electrode layer 4, the width dimension D1 of the gap G is preferably 500 μm or lower, more preferably 450 μm or lower, and still more preferably 400 μm or lower. When the width dimension D1 of the gap G is large, the area of the electrode layer 4 in a plan view relatively decreases. For example, when the electrode layer 4 is used as an electrode for electrostatic adsorption, the width dimension D1 of the gap G increases, the area of the electrode layer 4 decreases, and the electrostatic adsorption force decreases. That is, when the width dimension D1 of the gap G exceeds 500 μm, there is a concern that the function of the electrode layer 4 may decrease. By adjusting the width dimension D1 of the gap G to be 500 μm or lower, an extreme decrease in the function of the electrode layer 4 can be suppressed.

The gap G having the width dimension D1 exceeding 0 μm only needs to be provided between the outer edge 4c of the electrode layer 4 and the inner edge 6a of the joining layer 6. The width dimension D1 is more preferably 50 μm or higher and still more preferably 60 μm or higher. That is, the width dimension of the gap G between the outer edge 4c of the electrode layer 4 and the inner edge 6a of the joining layer 6 is preferably 50 μm or higher. By adjusting the width dimension D1 to be 50 μm or higher, the protrusion of the electrode layer 4 from the recess portion 7A can be reliably suppressed, irrespective of the shrinkage amount during the sintering of the electrode layer 4.

The width dimension D1 of the gap G may be higher than 0 μm and 500 μm or lower, preferably 50 μm or higher and 500 μm or lower, more preferably 50 μm or higher and 450 μm or lower, and still more preferably 60 μm or higher and 450 μm or lower.

In the present embodiment, the width dimension D1 of the gap G is measured based on an image obtained by imaging a cross-section of the ceramic joined body 1 with an electron microscope at a magnification of 1000-fold. The cross-section of the ceramic joined body 1 to be imaged is a cross-section passing through the center in the plane direction of the electrode layer 4, and when a minimum circle among circles circumscribing the ceramic joined body 1 in a plan view is assumed as shown in FIG. 1, is a cross-section of the ceramic joined body taken along a virtual plane including the center of the circle.

When two gaps G positioned on opposite sides in the side surface direction with respect to the center of the electrode layer 4 are provided in an imaging range of the electron microscope image of the cross-section, the width dimensions D1 of the two gaps G may be measured, respectively, and the wider width dimension D1 among the width dimensions D1 of the two gaps G may be in the above-described range of the width dimension D1.

According to the present embodiment, the inner edge 6a of the joining layer 6 has an inclination with respect to the thickness direction of the pair of ceramic plates 2 and 3, the electrode layer 4, and the joining layer. Therefore, the exposed area with respect to the gap G of the inner edge 6a of the joining layer 6 can be widened, and charge accumulated in the gap G can be widely distributed on the surface exposed to the gap G side of the joining layer 6. As a result, concentration and accumulation of charge in a part of the gap G can be suppressed, and breakdown caused by the local concentration of charge can be suppressed, and the withstand voltage of the ceramic joined body 1 can be increased.

In the present embodiment, the inner edge 6a of the joining layer 6 linearly extends in the cross-section shown in FIG. 1. That is, the inner edge 6a of the joining layer 6 is a surface that linearly connects the position B on the bottom surface 7c and the position A on the joint surface 7a in the cross-section. However, the inner edge 6a does not need to be an inclined surface that linearly extends. For example, the inner edge 6a may be a surface that connects the position B and the position A in the cross-section with a curved line.

### (Ceramic Plate and Joining Layer)

Shapes of outer peripheries of overlapping surfaces of the first ceramic plate 2 and the second ceramic plate 3 are made the same. The thicknesses of the first ceramic plate 2 and the second ceramic plate 3 are not particularly limited and can be appropriately adjusted depending on the use of the ceramic joined body 1.

In the present embodiment, the first ceramic plate 2 and the second ceramic plate 3 have the same composition or include the same major component. However, the compositions of the first ceramic plate 2 and the second ceramic plate 3 may be different from each other.

In the present embodiment, the joining layer 6 may be integrally formed with the second ceramic plate 3. Accordingly, the joining layer 6 and the second ceramic plate 3 have the same composition. However, when the joining layer 6 and the ceramic plates 2 and 3 are laminated as separate members, the compositions of the joining layer 6 and the ceramic plates 2 and 3 may be different from each other.

The first ceramic plate 2, the second ceramic plate 3, and the joining layer 6 according to the present embodiment is formed of a composite of an insulating material and a conductive material. When the ceramic plates 2 and 3 include the conductive material, the ceramic plates 2 and 3 have conductivity, and charge accumulated in the joint interface between the ceramic plates 2 and 3 and the electrode layer 4 can be uniformly distributed in a plane of the joint interface. Further, by allowing the joining layer 6 to include the conductive material, charge accumulated in the joint interface between the ceramic plates 2 and 3 and the electrode layer 4 can be uniformly distributed in a plane of the joint interface. According to the present embodiment, the local concentration of charge in the joint interface can be suppressed, and discharge from the joint interface can be suppressed.

One of the pair of ceramic plates 2 and 3 does not need to include the conductive material. As long as at least one of the pair of ceramic plates 2 and 3 includes the conductive material, charge can be dispersed in the joint interface in any one of the +Y direction or the −Y direction, and discharge from the joint interface can be suppressed. That is, by allowing at least one of the pair of ceramic plates 2 and 3 and the joining layer 6 to be formed of the composite of the insulating material and the conductive material, the breakdown of the ceramic joined body 1 can be suppressed.

In at least one of the pair of ceramic plates 2 and 3 and the joining layer 6 that include the conductive material, the conductive material is uniformly dispersed in the entire base material including the insulating material. Therefore, charge can be appropriately dispersed through the gap G without the occurrence of breakdown. This effect cannot be obtained when the ceramic plates 2 and 3 and the joining layer 6 are formed of only the conductive material or when the conductive material is locally provided in the ceramic plates 2 and 3 and the joining layer.

A content ratio of the conductive material in the at least one of the pair of ceramic plates 2 and 3 and the joining layer 6 is preferably 3% by mass or more and 12% by mass or less. By adjusting the content ratio of the conductive material to be 3% by mass or more, charge can be appropriately dispersed, and the bias of charge of the gap G can be suppressed, and the withstand voltage can be increased. In addition, when the content ratio of the conductive material is less than 3% by mass, excessive grain growth of the insulating material during joining is suppressed, and thus the joining temperature needs to be decreased. A decrease in joining temperature causes a decrease in the density of the electrode layer 4, and a sufficient function for the electrode layer is not exhibited. Therefore, the content ratio of the conductive material is preferably 3% by mass or more. On the other hand, when the content ratio of the conductive material is excessively high, there is a concern that the withstand voltage may decrease. Therefore, the content ratio of the conductive material is preferably 12% by mass or less. The content ratio of the conductive material is more preferably 10% by mass or less, still more preferably 8% by mass or less, and still more preferably 6% by mass or less.

The insulating material in the first ceramic plate 2, the second ceramic plate 3, and the joining layer 6 is preferably at least one selected from the group consisting of Al₂O₃, AlN, silicon nitride (Si₃N₄), Y₂O₃, YAG, samarium-aluminum oxide (SmAlO₃), magnesium oxide (MgO), and silicon oxide (SiO₂). In particular, Al₂O₃ or AlN is preferable.

The conductive material in the first ceramic plate 2, the second ceramic plate 3, and the joining layer 6 is preferably at least one selected from the group consisting of SiC, TiO₂, TiN, TiC, tungsten (W), tungsten carbide (WC) molybdenum (Mo), molybdenum carbide (Mo₂C), and a carbon material (C). In particular, SiC is preferable.

The material of the first ceramic plate 2, the second ceramic plate 3, and the joining layer 6 is not particularly limited as long as it has a volume specific resistance value of about 10¹³ Ω·cm or higher and 10¹⁷ Ω·cm or lower, has a mechanical strength, and has durability to corrosive gas and plasma thereof. Examples of the material include an Al₂O₃ sintered compact, an AlN sintered compact, and an Al₂O₃—SiC composite sintered compact. From the viewpoints of dielectric characteristics, high corrosion resistance, plasma resistance, and heat resistance at a high temperature, it is preferable that the material of the first ceramic plate 2, the second ceramic plate 3, and the joining layer 6 is an Al₂O₃—SiC composite sintered compact.

The average primary particle diameter of the insulating material forming the first ceramic plate 2, the second ceramic plate 3, and the joining layer 6 is preferably 0.5 μm or higher and 3.0 μm or lower, more preferably 0.7 μm or higher and 2.0 μm or lower, and still more preferably 1.0 μm or higher and 2.0 μm or lower.

When the average primary particle diameter of the insulating material forming the first ceramic plate 2, the second ceramic plate 3, and the joining layer 6 is 0.5 μm or higher, the first ceramic plate 2, the second ceramic plate 3, and the joining layer 6 that are dense, have high voltage endurance, and have high durability can be obtained. When the average primary particle diameter of the insulating material forming the first ceramic plate 2, the second ceramic plate 3, and the joining layer 6 is 3.0 μm or lower, insulating characteristics are likely to be ensured, and processing such as grinding is simple.

A method of measuring the average primary particle diameter of the insulating material forming the first ceramic plate 2, the second ceramic plate 3, and the joining layer 6 is as follows. Using a field emission scanning electron microscope manufactured by JEOL Ltd. (FE-SEM; manufactured by JEOL Ltd., JSM-7800F-Prime), a cut surface of the first ceramic plate 2, the second ceramic plate 3, and the joining layer 6 in the thickness direction is observed at a magnification of 10000-fold, and the average particle diameter of 200 particles of the insulating material is obtained as the average primary particle diameter using an intercept method.

### (Electrode Layer)

The electrode layer 4 is configured to be used as, for example, an electrode for plasma generation that applies high frequency power to generate plasma for a plasma treatment, an electrode for an electrostatic chuck that generates charges and fixes a plate-shaped sample due to an electrostatic adsorption force, or a heater electrode that heats a plate-shaped sample by electric heating. The shape of the electrode layer 4 (the shape of the electrode layer 4 when seen in a plan view) or the size thereof (the thickness or the area of the electrode layer 4 when seen in a plan view) is not particularly limited and is appropriately adjusted depending on the use of the ceramic joined body 1.

The electrode layer 4 is formed of a compound material (sintered compact) of particles of an insulating ceramic (insulating material) and particles of a conductive ceramic (conductive material).

The insulating ceramic in the electrode layer 4 is not particularly limited and is preferably, for example, at least one selected from the group consisting of Al₂O₃, AlN, silicon nitride (Si₃N₄), Y₂O₃, YAG, samarium-aluminum oxide (SmAlO₃), magnesium oxide (MgO), and silicon oxide (SiO₂).

The conductive ceramic (conductive material) in the electrode layer 4 is preferably at least one selected from the group consisting of SiC, TiO₂, TiN, TiC, tungsten (W), tungsten carbide (WC), molybdenum (Mo), molybdenum carbide (Mo₂C), a carbon material, and a conductive composite sintered compact.

Examples of the carbon material include carbon black, carbon nanotubes, and carbon nanofibers.

Examples of the conductive composite sintered compact include Al₂O₃—Ta₄C₅, Al₂O₃—W, Al₂O₃—SiC, AlN—W, and AlN—Ta.

The conductive material in the electrode layer 4 is formed of at least one selected from the group consisting of the above-described materials such that the conductivity of the electrode layer can be ensured.

The electrode layer 4 is formed of the conductive material and the insulating material, and the joint strength of the first ceramic plate 2 and the second ceramic plate 3 and the mechanical strength as an electrode are strong.

The insulating material in the electrode layer 4 is Al₂O₃ such that dielectric characteristics, high corrosion resistance, plasma resistance, and heat resistance at a high temperature are maintained.

A ratio (mixing ratio) between the contents of the conductive material and the insulating material in the electrode layer 4 is not particularly limited and is appropriately adjusted depending on the use of the ceramic joined body 1.

The electrode layer 4 may have the same relative density as a whole. In addition, the density of the electrode layer 4 in the outer edge may be lower than that at the center of the electrode layer 4. The density (relative density) of the electrode layer 4 is obtained from a microscope image of the cross-section of the ceramic joined body 1.

The present invention is not limited to the above-described embodiment.

For example, as described above, in the ceramic joined body, the second ceramic plate 3 and the joining layer 6 may be individually laminated as separate members, and an interface may be joined.

The ceramic joined body may have a shape in which the inner edge 6a of the joining layer 6 is gently curved.

In addition, the ceramic joined body may have a configuration where the electrode layer 4 is provided in each of configurations corresponding to the laminated portion 7 according to the above-described embodiment and the configurations are inverted, laminated, and joined to each other in the thickness direction.

### [Method for Manufacturing Ceramic Joined Body]

A method for manufacturing the ceramic joined body 1 according to the present embodiment includes: a step of forming a recess portion in at least one of a pair of ceramic plates, the recess portion having an inclined surface that is inclined with respect to a thickness direction of the pair of ceramic plates on a surface where the pair of ceramic plates overlap each other (hereinafter, also referred to as “first step”); a step of applying a paste for formation of electrode layer to the recess portion to form an electrode layer coating film (hereinafter, also referred to as “second step”); a step of laminating the pair of ceramic plates such that a surface where the electrode layer coating film is formed faces inward (hereinafter, referred to as “third step”); and a step of pressurizing a laminated body including the pair of ceramic plates and the electrode layer coating film in the thickness direction while heating the laminated body (hereinafter, referred to as “fourth step”).

Hereinafter, the method for manufacturing the ceramic joined body 1 according to the present embodiment where the electrode layer 4 is provided between the pair of ceramic plates 2 and 3 will be described with reference to FIGS. 6 to 8.

In the first step shown in FIG. 6, for example, the laminated portion 7 is formed, in which a recess portion is formed in a ceramic plate material 70 having the same composition as that of the second ceramic plate, and the second ceramic plate 3 and the joining layer 6 are laminated. On a surface 70a of the ceramic plate material 70 (the joint surface 7a of the laminated portion 7), the recess portion 7A having the side wall surface 7d that is inclined with respect to the thickness direction of the laminated portion 7 is formed. In order to form the recess portion 7A, blasting, grinding, or polishing may be performed on the surface 70a.

In addition, in the laminated portion 7, when the second ceramic plate 3 and the joining layer 6 are separate members, the recess portion 7A can be formed by providing the annular joining layer 6 on one surface of the second ceramic plate 3. That is, the first step is a step of forming the recess portion 7A in at least one of the pair of ceramic plates 2 and 3.

In the second step shown in FIG. 7, the paste for formation of electrode layer is applied to the bottom surface 7c of the recess portion 7A using a coating method such as a screen printing method, and a solvent in the paste for formation of electrode layer is further volatilized to form a coating film (electrode layer coating film 4A) for forming the electrode layer 4. An outer edge of the electrode layer coating film 4A faces the side wall surface 7d of the recess portion 7A through a gap therebetween. That is, the second step is a step of forming the electrode layer coating film 4A on the bottom surface 7c of the recess portion 7A. In the second step, it is preferable to use the coating method such as a screen printing method because the formation position of the electrode layer coating film 4A can be strictly controlled and the gap can be reliably formed between the electrode layer coating film 4A and the side wall surface 7d of the recess portion 7A.

As the paste for formation of electrode layer, a dispersion where the particles of the insulating ceramic and the particles of the conductive ceramic for forming the electrode layer 4 are dispersed in a solvent is used. As the solvent in the paste for formation of electrode layer, for example, an alcohol such as isopropyl alcohol is used.

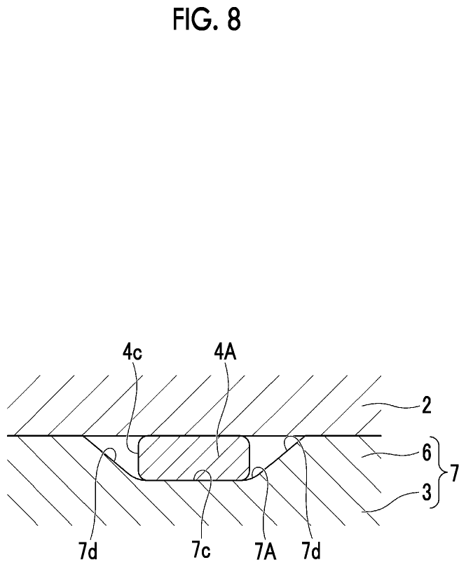

In the third step shown in FIG. 8, the first ceramic plate 2 is laminated on the joint surface 7a of the laminated portion 7 such that a surface where the electrode layer coating film 4A is formed faces inward. That is, the third step is a step of laminating the pair of ceramic plates 2 and 3 to cover the opening of the recess portion 7A.

In the fourth step, a laminated body including the first ceramic plate 2, the electrode layer coating film 4A, and the laminated portion 7 is pressurized in the thickness direction while being heated. That is, the fourth step is a step of pressurizing the pair of ceramic plates 2 and 3 laminated in the third step in the thickness direction while heating the pair of ceramic plates 2 and 3.

The atmosphere in which the laminated body is pressurized in the thickness direction while being heated is preferably a vacuum or an inert atmosphere such as Ar, He, or N₂. Here, “vacuum” refers to “a state of a space that is filled with gas at a lower pressure than the typical atmospheric pressure as described in JISZ 8126-1:1999”.

A temperature (heat treatment temperature) at which the laminated body is heated is preferably 1400° C. or higher and 1900° C. or lower and more preferably 1500° C. or higher and 1850° C. or lower.

When the temperature at which the laminated body is heated is 1400° C. or higher and 1900° C. or lower, the electrode layer 4 can be formed in the recess portion 7A. In addition, the ceramic plates 2 and 3 can be joined and integrated through the joining layer 6.

The pressure (welding pressure) at which the laminated body is pressurized in the thickness direction is preferably 1.0 MPa or higher and 50.0 MPa or lower and more preferably 5.0 MPa or higher and 20.0 MPa or lower.

When the pressure at which the laminated body is pressurized in the thickness direction is 1.0 MPa or higher and 50.0 MPa or lower, the electrode layer 4 can be formed between the first ceramic plate 2 and the second ceramic plate 3. In addition, the first ceramic plate 2 and the laminated portion 7 can be joined and integrated through the electrode layer 4.

With the method for manufacturing the ceramic joined body 1 according to the present embodiment, the outer edge of the electrode layer coating film 4A that is applied into the recess portion 7A is disposed inside the side wall surface 7d of the recess portion 7A through the gap. That is, in the method for manufacturing the ceramic joined body 1 according to the present embodiment, in the second step, the gap is provided between the outer edge of the electrode layer coating film 4A and the side wall surface 7d of the recess portion 7A. Therefore, by shrinking the electrode layer coating film 4A to form the electrode layer 4, the gap G is reliably provided between an outer edge 4c of the electrode layer 4 and the side wall surface 7d of the recess portion 7A in the present embodiment. With the method for manufacturing the ceramic joined body 1 according to the present embodiment, the ceramic joined body 1 can be provided, in which when a high voltage is applied to the electrode layer 4, discharge in the joint surface 7a can be suppressed, and breakdown caused by discharge can be suppressed.

In the method for manufacturing the ceramic joined body 1 according to the present embodiment, the ceramic plates 2 and 3 that are sintered in advance are joined. Therefore, the deformation of the ceramic plates 2 and 3 is likely to occur, and the dimension of the gap G provided in the periphery of the electrode layer 4 is easily controlled. That is, in the method for manufacturing the ceramic joined body 1 according to the present embodiment, the gap G having a size of 50 μm or higher is likely to be uniformly formed along the outer periphery of the electrode layer 4.

When a green sheet is laminated instead of the ceramic plate to form a ceramic joined body, the gap changes due to deformation caused by a pressure during the lamination or due to shrinkage during calcination. Therefore, it is difficult to form the uniform gap G.

In the method for manufacturing the ceramic joined body 1 according to the present embodiment, the electrode layer coating film 4A is formed on the bottom surface 7c of the recess portion 7A. Therefore, the positional accuracy of the electrode layer 4 in the ceramic joined body 1 can be ensured only the positional accuracy of the coating method. In the method for manufacturing the ceramic joined body 1 according to the present embodiment, the dimensional accuracy of the gap G provided between the outer edge of the electrode layer 4 and the side wall surface 7d is likely to be improved.

When the electrode layer coating film 4A is formed on the ceramic plate 2 on the side that covers the recess portion 7A, the positional accuracy of the electrode layer 4 in the ceramic joined body 1 depends not only on the positional accuracy of the coating method but also on the positional accuracy of the lamination between the ceramic plates 2 and 3.

In the second step according to the present embodiment, a thickness dimension H of the electrode layer coating film 4A is preferably 0.85 times or higher and 1.5 times or lower with respect to a depth dimension D of the recess portion 7A. By adjusting the thickness dimension H of the electrode layer coating film 4A to be 0.85 times or higher with respect to the depth dimension D, the contact between the electrode layer coating film 4A and the ceramic plate 2 can be reliably ensured. In addition, by adjusting the thickness dimension H of the electrode layer coating film 4A to be 0.85 times or higher with respect to the depth dimension D, the electrode layer coating film 4A can support the ceramic plate 2 and excessive deformation of the ceramic plate 2 can be suppressed against the pressurization in the fourth step. On the other hand, when the thickness dimension H is excessively large, the contact between the ceramic plates 2 and 3 is insufficient, and there is a concern that the withstand voltage between the ceramic plates 2 and 3 may decrease. Therefore, it is preferable that the thickness dimension H of the electrode layer coating film 4A is 1.5 times or lower with respect to the depth dimension D.

### [Electrostatic Chuck Device]

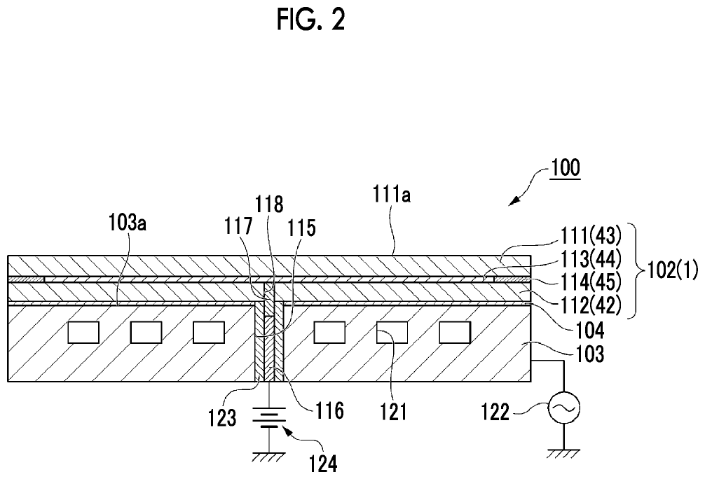

Hereinafter, an electrostatic chuck device according to an embodiment of the present invention will be described with reference to FIG. 2.

FIG. 2 is a cross-sectional view showing the electrostatic chuck device according to the present embodiment. In FIG. 2, the same components as those of the above-described ceramic joined body are represented by the same reference numerals, and the repeated description thereof will not be repeated.

As shown in FIG. 2, an electrostatic chuck device 100 according to the present embodiment includes: a disk-shaped electrostatic chuck member 102; a disk-shaped base member 103 for temperature adjustment that adjusts the electrostatic chuck member 102 to a desired temperature; and an adhesive layer 104 that joins and integrates the electrostatic chuck member 102 and the base member 103 for temperature adjustment. In the electrostatic chuck device 100 according to the present embodiment, the electrostatic chuck member 102 is, for example, the ceramic joined body 1 according to the present embodiment. Here, a case where the electrostatic chuck member 102 is the ceramic joined body 1 will be described.

In the following description, a placing surface 111a side of a placing plate 111 is set as “upper side” and the base member 103 side for temperature adjustment is set as “lower side” to represent relative positions of the components.

### [Electrostatic Chuck Member]

The electrostatic chuck member 102 includes: the placing plate 111 that is formed of a ceramic and has, as an upper surface, the placing surface 111a on which a plate-shaped sample such as a semiconductor wafer (silicon wafer) is placed; a supporting plate 112 that is provided on a surface side of the placing plate 111 opposite to the placing surface 111a; an electrostatic adsorption electrode 113 that is interposed between the placing plate 111 and the supporting plate 112; an annular insulating material 114 that surrounds the periphery of the electrostatic adsorption electrode 113 interposed between the placing plate 111 and the supporting plate 112; and a power-feeding terminal 116 that is provided in a fixing hole 115 of the base member 103 for temperature adjustment to be in contact with the electrostatic adsorption electrode 113.

In the electrostatic chuck member 102, the placing plate 111 corresponds to the second ceramic plate 3, the supporting plate 112 corresponds to the first ceramic plate 2, the electrostatic adsorption electrode 113 corresponds to the electrode layer 4, and the insulating material 114 corresponds to the joining layer 6.

### [Placing Plate]

On the placing surface 111a of the placing plate 111, a plurality of protuberances for supporting the plate-shaped sample such as a semiconductor wafer are formed (not shown). Further, in order to prevent leakage of cold gas such as helium (He) in a peripheral portion of the placing surface 111a of the placing plate 111, an annular protuberance having a square shape in cross-section may be provided to surround the peripheral portion. Further, in a region around the annular protuberance on the placing surface 111a, a plurality of protuberances that have the same height as the annular protuberance, have a circular shape in cross-section, and have a substantially rectangular shape in vertical section may be provided.

The thickness of the placing plate 111 is preferably 0.3 mm or higher and 3.0 mm or lower and more preferably 0.5 mm or higher and 1.5 mm or lower. When the thickness of the placing plate 111 is 0.3 mm or higher, a sufficient withstand voltage can be obtained. On the other hand, when the thickness of the placing plate 111 is 3.0 mm or lower, the electrostatic adsorption force of the electrostatic chuck member 102 does not decrease, thermal conductivity between the plate-shaped sample placed on the placing surface 111a of the placing plate 111 and the base member 103 for temperature adjustment does not deteriorate, and the temperature of the plate-shaped sample that is being processed can be maintained at a given preferable temperature.

The width dimension of the annular protuberance is preferably in a range of 1.5 mm or higher and 10 mm or lower. When the width dimension of the annular protuberance is 1.5 mm or higher, He gas is not likely to leak between a back surface of the plate-shaped sample and an upper surface of the annular protuberance. As a result, the temperature of the plate-shaped sample during a plasma treatment is likely to be uniformly maintained in the entire plate-shaped sample.

In addition, when the width dimension of the annular protuberance is 10 mm or lower, charge is not likely to remain on the surface of the annular protuberance. In this case, the outer peripheral portion of the plate-shaped sample is likely to peel off when the plate-shaped sample is removed, and damage of the plate-shaped sample during the removal can be suppressed. In addition, the contact area between the plate-shaped sample and the annular protuberance can be suppressed. As a result, a difference between the heat capacity that moves from the plate-shaped sample to the placing plate in the inner peripheral portion of the plate-shaped sample and the heat capacity that moves in the outer peripheral portion is not likely to be generated. As a result, the temperature of the plate-shaped sample during a plasma treatment is likely to be uniformly maintained in the entire plate-shaped sample.

The height of the annular protuberance is preferably 10 μm or higher and 30 μm or lower. By adjusting the height of the annular protuberance to be 10 μm or higher and 30 μm or lower, the temperature of the plate-shaped sample is likely to be uniformly maintained in the entire plate-shaped sample.

### [Supporting Plate]

The supporting plate 112 supports the placing plate 111 and the electrostatic adsorption electrode 113 from the lower side.

The thickness of the supporting plate 112 is preferably 0.3 mm or higher and 3.0 mm or lower and more preferably 0.5 mm or higher and 1.5 mm or lower. When the thickness of the supporting plate 112 is 0.3 mm or higher, a sufficient withstand voltage can be ensured. On the other hand, when the thickness of the supporting plate 112 is 3.0 mm or lower, the electrostatic adsorption force of the electrostatic chuck member 102 does not decrease, thermal conductivity between the plate-shaped sample placed on the placing surface 111a of the placing plate 111 and the base member 103 for temperature adjustment does not deteriorate, and the temperature of the plate-shaped sample that is being processed can be maintained at a given preferable temperature.

### [Electrostatic Adsorption Electrode]

In the electrostatic adsorption electrode 113, by applying a voltage, the electrostatic adsorption force with which the plate-shaped sample is supported on the placing surface 111a of the placing plate 111 is generated.

The thickness of the electrostatic adsorption electrode 113 is preferably 5 μm or higher and 200 μm or lower, more preferably 7 μm or higher and 100 μm or lower, and still more preferably 10 μm or higher and 100 μm or lower. When the thickness of the electrostatic adsorption electrode 113 is 5 μm or higher, sufficient conductivity can be ensured. On the other hand, when the thickness of the electrostatic adsorption electrode 113 is 200 μm or lower, thermal conductivity between the plate-shaped sample placed on the placing surface 111a of the placing plate 111 and the base member 103 for temperature adjustment does not deteriorate, and the temperature of the plate-shaped sample that is being processed can be maintained at a given desirable temperature. In addition, plasma permeability does not deteriorate, and plasma can be stably generated.

### [Insulating Material]

The insulating material 114 is a member that surrounds the electrostatic adsorption electrode 113 to protect the electrostatic adsorption electrode 113 from corrosive gas and plasma thereof.

Due to the insulating material 114, the placing plate 111 and the supporting plate 112 are joined and integrated through the electrostatic adsorption electrode 113.

### [Power-Feeding Terminal]

The power-feeding terminal 116 is a member that applies a voltage to the electrostatic adsorption electrode 113.

The number, the shape, and the like of the power-feeding terminals 116 are determined depending on the form of the electrostatic adsorption electrode 113, that is, whether the electrostatic adsorption electrode 113 is unipolar or bipolar.

The material of the power-feeding terminal 116 is not particularly limited as long as it is the conductive material having excellent heat resistance. As the material of the power-feeding terminal 116, a material having a thermal expansion coefficient similar to those of the electrostatic adsorption electrode 113 and the supporting plate 112 is preferable. For example, a metal material such as a Kovar alloy or niobium (Nb) and various conductive ceramics are suitably used.

### [Conductive Adhesive Layer]

A conductive adhesive layer 117 is provided in the fixing hole 115 of the base member 103 for temperature adjustment and in a through-hole 118 of the supporting plate 112. In addition, the conductive adhesive layer 117 is interposed between the electrostatic adsorption electrode 113 and the power-feeding terminal 116 and electrically connects the electrostatic adsorption electrode 113 and the power-feeding terminal 116 to each other.

A conductive adhesive forming the conductive adhesive layer 117 includes a conductive material such as carbon fibers or metal powder and a resin.

The resin in the conductive adhesive is not particularly limited as long as it suppresses the occurrence of cohesive failure caused by thermal stress. Examples of the resin include a silicone resin, an acrylic resin, an epoxy resin, a phenol resin, a polyurethane resin, and an unsaturated polyester resin.

Among these, a silicone resin is preferable from the viewpoints that the degree of expansion and contraction is high and cohesive failure caused by a change in thermal stress is not likely to occur.

### [Base Member for Temperature Adjustment]

The base member 103 for temperature adjustment is a disk-shaped thick member formed of at least one of a metal or a ceramic. The body of the base member 103 for temperature adjustment is configured to function as an internal electrode for generating a plasma. In the body of the base member 103 for temperature adjustment, a flow path 121 for circulating a coolant such as water, He gas, or N₂ gas is formed.

The body of the base member 103 for temperature adjustment is connected to an external high frequency power supply 122. In addition, in the fixing hole 115 of the base member 103 for temperature adjustment, the power-feeding terminal 116 of which the outer periphery is surrounded by an insulating material 123 is fixed through the insulating material 123. The power-feeding terminal 116 is connected to an external direct current power supply 124.

A material forming the base member 103 for temperature adjustment is not particularly limited as long as it is a metal having excellent thermal conductivity, electrical conductivity, and workability or a compound material including the metal. As the material for forming the base member 103 for temperature adjustment, for example, aluminum (Al), copper (Cu), stainless steel (SUS), or titanium (Ti) is suitably used.

It is preferable that at least a surface of the base member 103 for temperature adjustment that is exposed to a plasma undergoes an alumite treatment or is coated with a resin such as a polyimide resin. In addition, it is more preferable that the entire surface of the base member 103 for temperature adjustment undergoes an alumite treatment or is coated with a resin.

The base member 103 for temperature adjustment undergoes an alumite treatment or is coated with a resin such that plasma resistance of the base member 103 for temperature adjustment is improved and abnormal discharge is prevented. Accordingly, the plasma resistance stability of the base member 103 for temperature adjustment can be improved, and surface scratches of the base member 103 for temperature adjustment can also be prevented.

### [Adhesive Layer]

The adhesive layer 104 is configured to bond and integrate the electrostatic chuck member 102 and the base member 103 for temperature adjustment.

The thickness of the adhesive layer 104 is preferably 100 μm or higher and 200 μm or lower and more preferably 130 μm or higher and 170 μm or lower.

When the thickness of the adhesive layer 104 is in the above-described range, the adhesion strength between the electrostatic chuck member 102 and the base member 103 for temperature adjustment can be sufficiently ensured. In addition, the thermal conductivity between the electrostatic chuck member 102 and the base member 103 for temperature adjustment can be sufficiently ensured.

A material of the adhesive layer 104 is formed of, for example, a cured product obtained by thermally curing a silicone resin composition, an acrylic resin, or an epoxy resin.

The silicone resin composition is a silicon compound having a siloxane bond (Si—O—Si) and is a resin having excellent heat resistance and elasticity, which is more preferable.

As the silicone resin composition, in particular, a silicone resin having a thermal curing temperature of 70° C. to 140° C. is preferable.

Here, it is not preferable that the thermal curing temperature is lower than 70° C. because, when the electrostatic chuck member 102 and the base member 103 for temperature adjustment are joined in a state where they face each other, curing does not progress sufficiently in the process of joining such that the workability deteriorates. On the other hand, it is not preferable that the thermal curing temperature is higher than 140° C. because a difference in thermal expansion between the electrostatic chuck member 102 and the base member 103 for temperature adjustment is large and stress between the electrostatic chuck member 102 and the base member 103 for temperature adjustment increases, which may cause peeling therebetween.

That is, it is preferable that the thermal curing temperature is 70° C. or higher because the workability in the process of joining is excellent, and it is preferable that the thermal curing temperature is 140° C. or lower because the electrostatic chuck member 102 and the base member 103 for temperature adjustment are not likely to peel off from each other.

In the electrostatic chuck device 100 according to the present embodiment, the electrostatic chuck member 102 is formed of the ceramic joined body 1. Therefore, in the electrostatic chuck member 102, the occurrence of breakdown (discharge) can be suppressed.

Hereinafter, a method for manufacturing the electrostatic chuck device according to the present embodiment will be described.

The electrostatic chuck member 102 formed of the ceramic joined body 1 obtained as described above is prepared.

An adhesive formed of a silicone resin composition is applied to a predetermined region of one principal surface 103a of the base member 103 for temperature adjustment. Here, the amount of the adhesive applied is adjusted such that the electrostatic chuck member 102 and the base member 103 for temperature adjustment can be joined and integrated.

Examples of a method for applying the adhesive include a method for manually applying the organic adhesive with a spatula, a bar coating method, and a screen printing method.

After applying the adhesive to the principal surface 103a of the base member 103 for temperature adjustment, the electrostatic chuck member 102 and the base member 103 for temperature adjustment to which the adhesive is applied are laminated.

In addition, the formed power-feeding terminal 116 is inserted into the fixing hole 115 that penetrates the base member 103 for temperature adjustment.

Next, the electrostatic chuck member 102 is pressed against the base member 103 for temperature adjustment at a predetermined pressure such that the electrostatic chuck member 102 and the base member 103 for temperature adjustment are joined and integrated. As a result, the electrostatic chuck member 102 and the base member 103 for temperature adjustment are joined and integrated through the adhesive layer 104.

As a result, the electrostatic chuck device 100 according to the present embodiment where the electrostatic chuck member 102 and the base member 103 for temperature adjustment are joined and integrated through the adhesive layer 104 can be obtained.

The plate-shaped sample according to the present embodiment is not limited to a semiconductor wafer and may be, for example, a glass substrate for a flat panel display (FPD) such as a liquid crystal display (LCD), a plasma display (PDP), or an organic EL display. In addition, the electrostatic chuck device according to the present embodiment may be designed according to the shape or size of the substrate.

### Modification Example

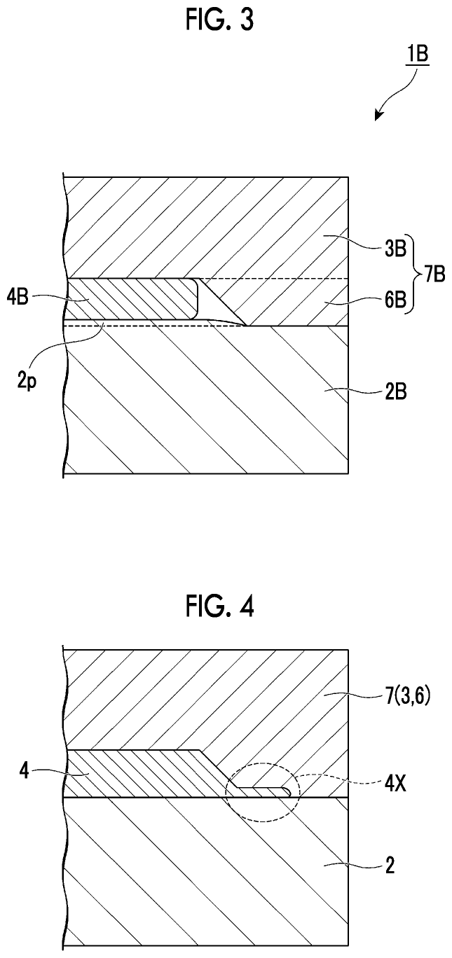

FIG. 3 is a partially schematic cross-sectional view showing a ceramic joined body 1B according to a modification example that can be adopted in the above-described embodiment.

The ceramic joined body according to the present modification example is different from the above-described embodiment, in that one ceramic plate 2B protrudes another ceramic plate 3B side in a portion overlapping an electrode layer 4B.

As in the above-described embodiment, the ceramic joined body 1B according to the present modification example includes: the pair of ceramic plates 2B and 3B; the electrode layer 4B that is interposed between the pair of ceramic plates 2B and 3B; and a joining layer 6B. As in the above-described embodiment, the joining layer 6B and the ceramic plate 3B are formed as a single member and configure a laminated body 7B.

In the present modification example, the one ceramic plate 2B includes a protrusion portion 2p, that protrudes to the other ceramic plate 3B side, in a portion of a surface thereof, which faces the other ceramic plate 3B, and the portion of the surface overlaps the electrode layer 4B when seen from the thickness direction. The protrusion portion 2p is a trace formed when a sufficient pressure is applied between the ceramic plate 2B and the laminated body 7B during joining therebetween. By providing the protrusion portion 2p, a sufficient pressure is also applied to the electrode layer 4B during the joining. In the present modification example, by applying a sufficient pressure to the electrode layer 4B in the thickness direction during the joining, the density of the electrode layer 4B can be improved, and the conductivity can be maintained.

### EXAMPLES

Hereinafter, the present invention will be described in detail using Example and Comparative Examples, but is not limited to the following examples.

### Examples

Mixed powder including 91% by mass to 97% by mass of aluminum oxide powder and 3% by mass to 9% by mass of silicon carbide powder was molded and sintered. As a result, a pair of ceramic plates formed of an aluminum oxide-silicon carbide composite sintered compact having a disk shape with a diameter of 450 mm and a thickness of 5.0 mm was manufactured.

Ratios between the aluminum oxide powder and the silicon carbide powder are collectively shown as SiC content ratios of respective Examples in Table 1 below.

One surface of one ceramic plate was ground, and a recess portion having an inclined surface that was inclined with respect to the thickness direction of the ceramic plate was formed in the one surface of the ceramic plate. The formed recess portion was circular in a plan view, and the opening diameter thereof gradually decreased in the thickness direction of the ceramic plate. As a result, the second ceramic plate and the joining layer were laminated to obtain a laminated portion. The thickness of the second ceramic plate was 0.5 mm.

The other ceramic plate was used as the first ceramic plate.

Using a screen printing method, a paste for formation of electrode layer was applied to the recess portion to form an electrode layer coating film. The amount of the electrode layer coating film applied was adjusted such that a gap having a width dimension D1 according to each of Examples below was formed.

As the paste for formation of electrode layer, a dispersion in which aluminum oxide powder and molybdenum carbide powder were dispersed in isopropyl alcohol was used. In the paste for formation of electrode layer, the content ratio of the aluminum oxide powder was 25% by mass, and the content ratio of the molybdenum carbide powder was 25% by mass.

Next, the second ceramic plate was laminated on the one surface of the first ceramic plate such that the surface where the electrode layer coating film was formed faced inward.

Next, a laminated body including the first ceramic plate, the electrode layer coating film, the insulating layer coating film, and the second ceramic plate (laminated portion) was pressurized in the thickness direction while heating the laminated body in an argon atmosphere. The heat treatment temperature was 1700° C., the welding pressure was 10 MPa, and the time for which the heat treatment and the pressurization were performed was 2 hours.

Through the above-described steps, ceramic joined bodies according to Examples 1 and 2 where the width dimensions D1 of the gaps were different were obtained. The width dimension D1 of each of Examples is shown in Table 1 below.

### Comparative Example 1

A ceramic joined body according to Comparative Example 1 was manufactured through the same procedure as that of Example described above, except that the electrode layer was caused to protrude from the recess portion by adjusting the amount of the electrode layer coating film applied to the recess portion. The amount of protrusion in Comparative Example 1 is shown in Table 1 below. In addition, FIG. 4 is a schematic cross-sectional view showing the ceramic joined body according to Comparative Example 1. In FIG. 4, a portion of the electrode layer 4 protruding from the recess portion is represented by reference numeral 4X.

### Comparative Example 2

A ceramic joined body according to Comparative Example 2 was manufactured through the same procedure as that of Example described above, except that the second ceramic plate and the joining layer were separately molded and the joining layer did not include silicon carbide (SiC) as the conductive material. The joining layer according to Comparative Example 2 was formed of only aluminum oxide. The width dimension D1 of Comparative Example 2 is shown in Table 1 below.

In addition, in Comparative Example 2, the joining layer did not include the conductive material (silicon carbide). Therefore, when the heat treatment temperature during joining of the ceramic plates is the same (1700° C.) as other Examples, the growth of particle diameter of the insulating material (aluminum oxide) of the joining layer during joining is not inhibited by the conductive material, the particle diameter of the joining layer material may be excessively large, and there is a concern that the insulating characteristics of the joining layer may deteriorate. Accordingly, in Comparative Example 2, the heat treatment temperature in the joining step of the ceramic plates was set to 1380° C.

### Comparative Example 3

A ceramic joined body according to Comparative Example 3 was manufactured through the same procedure as that of Example described above, except that the content of silicon carbide (SiC) as the conductive material in the first ceramic plate and the second ceramic plate was adjusted as shown in Table 1.

### Comparative Examples 4 and 5

Ceramic joined bodies according to Comparative Examples 4 and 5 was manufactured using the same method as that of Example described above, except that the ratio of the thickness dimension of the electrode layer coating film to the depth dimension of the recess portion was adjusted as shown in Table 1.

### Reference Example

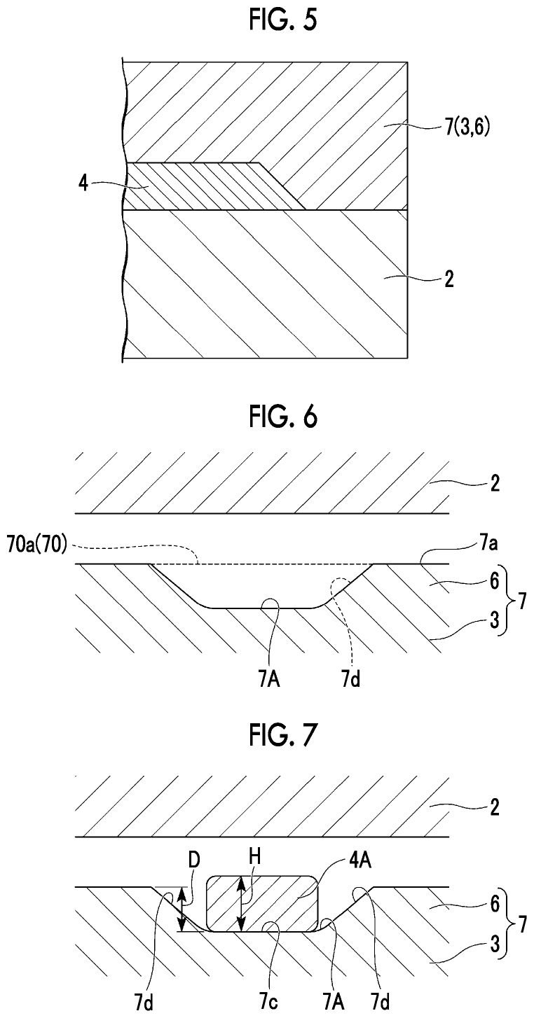

A ceramic joined body according to Reference Example was manufactured using the same method as that of Example described above, except that the gap was not provided between the outer edge of the electrode layer and the inner edge of the joining layer by adjusting the amount of the electrode layer coating film applied to the recess portion (that is, the width dimension of the gap=0). FIG. 5 is a schematic cross-sectional view showing the ceramic joined body according to Reference Example.

The manufacturing of the ceramic joined body having no gap and no protrusion as in Reference Example is not easy, and therefore only limited samples which were selected among a plurality of manufactured samples were adopted as Reference Example.

### [Evaluation Method]

### (Insulating Characteristics Evaluation)

The insulating characteristics were evaluated by measuring the withstand voltage. More specifically, a side surface withstand voltage as a withstand voltage of the ceramic joined body in the side surface direction and a dielectric layer withstand voltage as a withstand voltage in the thickness direction were measured as follows to evaluate the insulating characteristics.

In the first ceramic plate, a through-electrode was formed. The through-electrode is an electrode that penetrated the first ceramic plate in the thickness direction and reached the electrode layer from the surface of the first ceramic plate opposite to the surface in contact with the electrode layer. The through-electrode was electrically connected to the electrode layer.

For the measurement of the side surface withstand voltage, on a side surface (surface in the side surface direction) of the joining layer of the ceramic joined body, a carbon tape was bonded in a posture in contact with the first ceramic plate and the second ceramic plate. A voltage was applied to the ceramic joined body through the carbon tape and the through-electrode, and a voltage at which breakdown occurred in the ceramic joined body was measured. The side surface withstand voltage is a withstand voltage in the side surface direction of the ceramic joined body.

For the measurement of the dielectric layer withstand voltage, a silicon wafer was fixed to an upper surface of the second ceramic plate (dielectric layer), a voltage was applied to the ceramic joined body through the probe and the through-electrode, and a voltage at which breakdown occurred in the ceramic joined body was measured. The dielectric layer withstand voltage was a withstand voltage in the thickness direction of the ceramic joined body.

Specifically, for the measurement of the side surface withstand voltage and the dielectric layer withstand voltage, a voltage of 1000 V was applied and kept for 1 minute. Next, a voltage of 1000 V was gradually applied and was kept for 1 minute. When the measured current value exceeded 0.1 μA or when the discharge phenomenon occurred during the measurement, breakdown was assumed to occur, and a maximum applied voltage at which breakdown did not occur was obtained as the withstand voltage.

### (Width Dimension of Gap)

“The width dimension of the gap” was calculated from any scanning electron microscope image of a cross-section. That is, first, when a minimum circle among circles circumscribing the ceramic joined body in a plan view is assumed, the ceramic joined body was cut along a virtual plane including the center of the circle and parallel to the thickness direction. An electron microscope image of the obtained cross-section at a magnification of 1000-fold was obtained, and the dimension in the side surface direction of the gap in the electron microscope image was obtained as the width dimension D1.

### (Ratio of Thickness Dimension of Electrode Layer Coating Film to Depth Dimension of Recess Portion)

Regarding the ratio of the thickness dimension of the electrode layer coating film to the depth dimension of the recess portion, the paste for formation of electrode layer was applied to the recess portion, the applied paste was dried and solidified in a vacuum at 200° C. for 10 hours, the depth of the recess portion and the thickness dimension of the electrode layer coating film were measured using a laser non-contact thickness measurement system (measurement device name: LT-9000, manufactured by Keyence Corporation), and the above-described ratio was calculated based on the measurement results. The depth dimension of the recess portion and the thickness dimension of the electrode layer coating film were calculated by measuring four positions of 0°, 90°, 180°, and 270° in the circumferential direction in a plan view of the ceramic plate in a measurement range of 2 mm in the radial direction and averaging the measurement results of the four positions.

### [Evaluation Results]

Table 1 shows the width dimensions D1 of the gaps and the evaluation results of the insulating characteristics (that is, the withstand voltages in the side surface direction and the thickness direction) in Reference Example, Examples 1 and 2, and Comparative examples 1 to 5. In the fields of the withstand voltages in the side surface direction (side surface withstand voltages) of Reference Example, Examples 1 and 2, and Comparative examples 1 to 5, the percentages obtained by dividing the values of the measurement results by the value of the measurement result of the withstand voltage in the side surface direction of Reference example are described. Likewise, in the fields of the withstand voltages in the thickness direction (dielectric layer withstand voltage) of Reference Example, Examples 1 and 2, and Comparative examples 1 to 5, the percentages obtained by dividing the values of the measurement results by the value of the measurement result of the withstand voltage in the thickness direction of Reference example are described.

TABLE 1

| | | SiC | Thickness Dimension | | | |
|---|---|---|---|---|---|---|
| | Width | Content | of Electrode Layer | Withstand Voltage | | |
| | Dimension | Ratio | Coating Film/Depth | Side Surface | Thickness | |
| | of Gap | [% by | Dimension of Recess | Direction | Direction | |
| | [μm] | mass] | Portion | [%] | [%] | Note |
| Reference | 0 | 5 | 1.25 | 100 | 100 | |
| Example | | | | | | |
| Example 1 | 150 | 5 | 1.22 | 85 | 97 | |
| Example 2 | 200 | 5 | 1.23 | 84 | 102 | |
| Example 3 | 150 | 3 | 1.15 | 84 | 95 | |
| Example 4 | 150 | 9 | 1.33 | 80 | 85 | |
| Example 5 | 150 | 5 | 0.87 | 83 | 80 | |
| Example 6 | 150 | 5 | 1.48 | 82 | 80 | |
| Example 7 | 150 | 12 | 1.20 | 81 | 84 | |
| Comparative | −20 | 5 | Not Measured | 66 | 49 | Electrode Layer |
| Example 1 | (Protrusion) | | | | | Protruding from |
| | | | | | | Recess Portion |
| Comparative | 170 | 0 | Not Measured | 17 | 49 | Insulating Layer |
| Example 2 | | | | | | not Including |
| | | | | | | Conductive Material |
| Comparative | 150 | 15 | 1.25 | 32 | 45 | |
| Example 3 | | | | | | |
| Comparative | 150 | 5 | 1.61 | 25 | 60 | |
| Example 4 | | | | | | |
| Comparative | 150 | 5 | 0.54 | 50 | 55 | |
| Example 5 | | | | | | |

### [Consideration]

It was found from the result of Table 1 that the withstand voltage of the ceramic joined bodies according to Examples 1 to 7 was higher than that of the ceramic joined body according to Comparative Example 1. In the ceramic joined body according to Comparative Example 1, it is considered that the insulation protrudes from the recess portion such that discharge is likely to occur from the protrusion portion in the thickness direction and side surface direction.

In the ceramic joined body according to Comparative Example 2, it is considered that, since the joining layer does not include the conductive material, charge accumulated in the gap cannot be uniformly distributed and discharge is likely to occur in the thickness direction and the side surface direction due to the concentration of charge. In addition, in Comparative Example 2, since the heat treatment temperature during the joining of the ceramic plates needs to be low, an increase in density caused by the sintering of the electrode layer is insufficient. Therefore, in Comparative Example 2, the contact between the ceramic plates is insufficient.

In the ceramic joined body according to Comparative Example 3, it is considered that, since the content of the conductive material (SiC) in the ceramic plate exceeds 12% by mass, the withstand voltage decreases. It was able to be verified from the results of Examples and Comparative example 3 that, when the content ratio of the conductive material in the ceramic joined body was 3% by mass or more and 12% by mass or less, the withstand voltage of the ceramic joined body can be ensured.

In the ceramic joined body according to Comparative example 4, it is considered that, since the thickness dimension of the electrode layer coating film exceeds 1.5 times with respect to the depth dimension of the recess portion, the contact between the ceramic plates during hot press is insufficient, and the withstand voltage between the ceramic plates decreases.

In the ceramic joined body according to Comparative example 5, it is considered that, since the thickness dimension of the electrode layer coating film is lower than 0.85 times with respect to the depth dimension of the recess portion, the contact between the electrode layer coating film and the ceramic plate during hot press is insufficient, the amount of deformation of the ceramic plate during hot press is excessively large, and the withstand voltage decreases due to, for example, the occurrence of damage to the ceramic plate.

It was able to be verified from the results of Comparative Examples 4 and 5 that the withstand voltage of the ceramic joined body can be ensured by adjusting the ratio of the thickness dimension of the electrode layer coating film to the depth dimension of the recess portion to be in a range of 0.85 to 1.5.

### (Evaluation of Withstand Voltage of Ceramic Plate)

By using the ceramic plates according to Examples 1, 3, and 4 as test pieces, a test according to JIS C2110-2 was performed. The thicknesses of the test pieces were 3 mm, 1.5 mm, 0.7 mm, and 0.3 mm, and a voltage value at which the current value flowing through the test piece exceeded 1 μA was obtained as the withstand voltage. The withstand voltages of all the test pieces were 10 kV or higher.

It was found from this result that, when the minimum value of the width dimension of the joining layer is 0.3 mm or higher, the withstand voltage in the side surface direction can be ensured. In addition, it is considered that, when the minimum value of the width dimension of the joining layer is 3 mm or lower, the size of the internal electrode can be sufficiently ensured, and adsorption failure of the wafer outermost periphery can be suppressed.

### INDUSTRIAL APPLICABILITY

The ceramic joined body according to the present invention includes: a pair of ceramic plates; an electrode layer that is interposed between the pair of ceramic plates; and a joining layer that is disposed in a periphery of the electrode layer between the pair of ceramic plates, in which at least one of the pair of ceramic plates and the joining layer is formed of a composite of an insulating material and a conductive material, and a gap is provided between an outer edge of the electrode layer and an inner edge of the joining layer. Therefore, in the ceramic joined body according to the present invention, breakdown (discharge) in a joint interface between the ceramic plate and the conductive layer is suppressed. The ceramic joined body according to the present invention is suitably used for an electrostatic chuck member of an electrostatic chuck device, and the usefulness thereof is significantly high.

### REFERENCE SIGNS LIST

1, 1B: ceramic joined body
2, 2B: first ceramic plate (ceramic plate)
3, 3b: second ceramic plate (ceramic plate)
4: electrode layer
4c: outer edge
4A: electrode layer coating film
6, 6B: joining layer
6a: inner edge
7c: bottom surface
7d: side wall surface
7A: recess portion
100: electrostatic chuck device
102: electrostatic chuck member
103: base member for temperature adjustment
104: adhesive layer
D: depth dimension
G: gap
H: thickness dimension

1. A ceramic joined body comprising:
a pair of ceramic plates;
an electrode layer that is interposed between the pair of ceramic plates; and
a joining layer that is disposed in a periphery of the electrode layer between the pair of ceramic plates,
wherein the joining layer and at least one of the pair of ceramic plates are formed of a composite of an insulating material and a conductive material,
a gap is provided between an outer edge of the electrode layer and an inner edge of the joining layer, and
a content ratio of the conductive material in the joining layer and the at least one of the pair of ceramic plates is 3% by mass or more and 12% by mass or less.

2. The ceramic joined body according to claim 1,
wherein the inner edge of the joining layer has an inclination with respect to a thickness direction of the pair of ceramic plates, the electrode layer, and the joining layer.

3. The ceramic joined body according to claim 1,
wherein the insulating material is at least one selected from a group consisting of Al₂O₃, AlN, Si₃N₄, Y₂O₃, YAG, SmAlO₃, MgO, and SiO₂.

4. The ceramic joined body according to claim 1,
wherein the conductive material is at least one selected from a group consisting of SiC, TiO₂, TiN, TiC, W, WC, Mo, Mo₂C, and C.

5. The ceramic joined body according to claim 1,
wherein the joining layer is integrally formed with one of the pair of ceramic plates.

6. The ceramic joined body according to claim 1,
wherein a width dimension of the gap between the outer edge of the electrode layer and the inner edge of the joining layer is 50 μm or higher.

7. The ceramic joined body according to claim 1,
wherein at least one of the pair of ceramic plates includes a protrusion portion that protrudes to a side of an other one of the ceramic plates, and
the protrusion portion is located in a portion where a surface facing the other ceramic plate overlaps the electrode layer when seen from a thickness direction thereof.

8. The ceramic joined body according to claim 1,
wherein a minimum value of a width dimension of the joining layer is 0.3 mm or higher and 3 mm or lower.

9. An electrostatic chuck device,
wherein an electrostatic chuck member formed of a ceramic and a base member for temperature adjustment formed of a metal are joined through an adhesive layer, and
the electrostatic chuck member is formed of the ceramic joined body according to claim 1.

10. A method for manufacturing a ceramic-plate joined body in which an electrode layer is provided between a pair of ceramic plates, the method comprising:
a first step of forming a recess portion in at least one of the pair of ceramic plates;
a second step of forming an electrode layer coating film on a bottom surface of the recess portion;
a third step of laminating the pair of ceramic plates to cover an opening of the recess portion; and
a fourth step of pressurizing the pair of ceramic plates laminated in the third step in a thickness direction while heating the pair of ceramic plates,
wherein in the second step, a gap is provided between an outer edge of the electrode layer coating film and a side wall surface of the recess portion, and
in the second step, a thickness dimension of the electrode layer coating film is 0.85 times or higher and 1.5 times or lower with respect to a depth dimension of the recess portion.

11. The method for manufacturing a ceramic joined body according to claim 10,
wherein a joining layer, which has the side wall surface of the recess portion as an inner edge thereof, is formed from the at least one of the pair of ceramic plates in the first step.

12. The method for manufacturing a ceramic joined body according to claim 11,
wherein the joining layer and the at least one of the pair of ceramic plates is made of a composite of an insulating material and a conductive material, and
a content ratio of the conductive material in the composite is 3% by mass or more and 12% by mass or less.

13. The method for manufacturing a ceramic joined body according to claim 11, wherein the joining layer is integrally formed with the at least one of the pair of ceramic plates in the first step.
